(19) United States
(12) Patent Application Publication
(10) Pub. No.: US 2002/0113322 A1
(43) Pub. Date: Aug. 22, 2002

(54) Semiconductor device and method to produce the same

(76) Inventors: Shinichi Terashima, Futtsu-shi (JP); Yukihiro Yamamoto, Futtsu-shi (JP); Tomohiro Uno, Futtsu-shi (JP); Kohei Tatsumi, Futtsu-shi (JP)

Correspondence Address: KENYON & KENYON, ONE BROADWAY, NEW YORK, NY, 10004, US

(21) Appl. No.: 10/000,177

(22) Filed: Nov. 2, 2001

(30) Foreign Application Priority Data
Jun. 12, 2000 (JP) 2000-174909
Nov. 2, 2000 (JP) 2000-336520
Oct. 22, 2001 (JP) 2001-324002

(51) Int. Cl. H01L 23/48; H01L 23/52; H01L 29/40

(52) U.S. Cl. 257/784

(57) ABSTRACT

The present invention provides a semiconductor device, using a bonding wire for linking a semiconductor terminal to a connecting terminal for an outside circuit, capable of preventing short circuits of the bonding wires and excellent in strength and fatigue resistance of the bonding joints to cope with the downsizing of the terminals and the bonding materials, in which device the bonding wires are reinforced, partially or wholly, with a reinforcing material after bonding work and joint bulbs bonded to the terminals using bonding material are plated, and a method to produce the same.

### BACKGROUND OF THE INVENTION 1. Field of the Invention

The present invention relates to a resin-sealed semiconductor device composed of a semiconductor chip, a lead frame, a substrate, TAB tapes, etc. and bonding wires, and a method to produce the same.

2. Description of the Related Art

Generally speaking, connecting material for a semiconductor device is made of conductive material consisting of gold, copper, aluminum, tin or the like, and is used in the form of a bonding wire or a bump. In use, the connecting material is bonded to a terminal, made of aluminum or copper of a semiconductor. As a bonding wire is used without surface coating, when many of them are connected to the semiconductor terminals at a high density, short circuits may occur between wires, or between a wire and some other component. The higher the density of semiconductor devices, in particular, is advanced, the smaller the wire bonding pitch becomes and the more easily the short circuits occur. Besides, the wires often touch each other as they are bent during a process of sealing a semiconductor device with resin after the wires are bonded.

In a bonding joint between a bonding wire and a semiconductor terminal, a joint bulb is formed between the bonding wire proper and the semiconductor terminal through deformation of the bonding wire and, in the case of a bonding joint between terminals of two semiconductors using a bump as the connecting material, the joint bulb is formed through deformation of the bump. Usually, a diffusion layer of intermetallic compounds, solid solution, etc. gradually forms at the bonding joint between the connecting material and the terminal, and the diffusion layer undergoes chemical reactions with the outside environment. For instance, when the bonding joints are packaged with resin or a similar material, the diffusion layer may react with Br and/or other additive elements contained in the sealing resin, and, when the joints are not packaged, it may react with oxygen and/or the humidity in the air. Fatigue may also build up at the bonding joint as a result of thermal stress imposed on it during the use of the semiconductor device. The chemical reactions and the fatigue lower the bonding strength and, as a result, lead to a problem of poor bonding reliability in and around the joint bulbs.

Attempts have been made to enhance the strength and Young's modulus of a bonding wire in order to increase its linearity and decrease its bending during resin sealing work, for the purpose of preventing short circuits caused by the contact of a bonding wire with another bonding wire or other conductive portions of the device. Although the wire strength has been enhanced to some extent through measures such as alloying and high strength gold wires and other new bonding wires have been developed, the room for enhancing the wire strength beyond a certain level is very limited when problems related to bondability, etc. are considered. The use of high concentration alloy for an entire wire is not desirable either, since the high concentration of alloy elements increases the electric resistance of the wire. For these reasons, a gold bonding wire having a purity of 99.99% or higher and the similar are presently used for most bonding wires. Although the use of thicker bonding wires is effective for suppressing wire bending, the formation of micro bonding joints using thin wires is essential for finer pitch bonding when the expansion of the wire material at the bonding joints, caused by wire deformation, is taken into consideration. Besides, in the case of ball bonding, it is necessary to reduce the diameter of a ball formed at the end of a bonding wire, and this also requires the use of thin wires.

A bonding method to use a bonding wire coated with an insulating material was proposed, but the method has not been industrially applied because it is very difficult to bond the coated wire and secure sufficient bonding strength. In this situation, Japanese Unexamined Patent Publication No. S52-70657 proposes a bonding apparatus equipped with an insulating material feeder to feed to capillary guides a liquid insulating material having a prescribed adhesion. On the other hand, Japanese Unexamined Patent Publication No. S55-38014 proposes a wire bonding machine equipped with a means to coat the surface of bonding wires between terminals with liquid resin. Even when the wires are coated with the insulating material or the liquid resin, however, it is not easy to test and guarantee the integrity and reliability of the insulation when wires touch each other. Moreover, these wire bonding machines have problems that they are mechanically complicated and their productivity is low.

At most of the bonding joints of a semiconductor device, a bonding wire mainly composed of gold is bonded to a semiconductor terminal mainly composed of aluminum. When these joints are packaged with resin, the material of the joint bulb between the terminal and the bonding wire may be deteriorated. In such a case, corrosion products are observed at bonding joint sections. The corrosion products are formed through the chemical reactions of the intermetallic compounds of gold and aluminum formed at the bonding interface with the resin or Br and other additive elements contained in the resin. When these corrosion products are present, the required bonding strength is not secured and, what is more, the electric conductivity of the bonding joint is adversely affected, decreasing the service life of the device. There are cases in which a bump using a tin-lead eutectic alloy as the bonding material is bonded to a terminal composed mainly of copper. A diffusion layer of the tin-lead alloy and copper is formed at this kind of bonding joint and, every time an electric current is imposed, a thermal stress forms there owing to the difference in thermal expansion coefficients between the bonding material and the terminal material. As a result, cracks develop around the diffusion layer, and the bonding strength and conductivity of the bonding joint are deteriorated, decreasing the service life of the device. Common measures to improve the long-term reliability of bonding joints include, for instance, the addition of substances effective for preventing corrosion and enhancing fatigue resistance to bonding material. For the same purpose, Japanese Unexamined Patent Publication No. H8-288686 discloses a method to package a semiconductor device by resin sealing after the formation of bonding joints and then wrap the whole semiconductor package with a metal film by electroless plating, in order to prevent moisture absorption from outside. Another measure to plate the outer surface of the package by chemical treatment after the formation of bonding joints and packaging by resin sealing is also practiced. Japanese Unexamined Patent Publication No. H6-163783, for instance, proposes a method to plate terminals and other parts with nickel before the formation of bonding joints, in order to prevent liquid chemicals used in chemical treatment from forming a gap between the sealing resin and outer leads and the bonding joints from being corroded by humidity in the air penetrating through the gap.

After resin sealing, most of semiconductor devices are jointed to a mother-board by a joint material. At the joint, the device is heated over the melting point of the joint material in order to complete the joint. Because the tin-lead alloy solder are used for the joint material in many cases and its melting point is about 460K, the device is heated at about 500K at the joint. From the environmental view, the use of lead is tend to avoid and the practical use of the lead free solder is increasing. The melting point of the lead free solder is higher than that of the tin-lead alloy solder. For example, the melting point of the tin-silver alloy solder is over 500K. Therefore, the heat temperature at the joint of the device and the mother board by the lead free solder becomes much higher than that by the tin-lead alloy solder. As a result, a heat flux spreads to inside of the device, and the fracture at the bonding joint between a bonding wire and a connecting terminal occurs due to the thermal stress induced by the heat flux from outside of the device. In order to avoid the problem, a wire diameter tends to thicken.

### SUMMARY OF THE INVENTION

In response to the demands for higher density of wire bonding, or finer pitch bonding, of semiconductor devices, studies of high strength bonding wires and wires with insulation coating have been energetically pursued for the purpose of securing good bondability and preventing short circuits of the wires. However, presently available technologies are not sufficient for solving all the above problems satisfactorily. As higher performance of semiconductor devices is pursued, high density bonding is attempted and, as a consequence, the connecting materials and terminals are becoming smaller and smaller. Such a downsizing of the bonding parts inevitably results in a problem of smaller bonding areas. Thus, despite the demands for higher long-term reliability of bonding joints, the above problems have not been solved yet.

As higher demands of using the lead free solder, the joint temperature at the joint between a semiconductor device and a mother-board tends to increase. As a result, the problem of the fracture at the bonding joint tends to occur. On the other hand, wire diameter is required to decrease because of the downsizing of the bonding parts as mentioned above. Thus, despite the demands for of using the lead free solder, the above problem has not been solved yet.

In view of the above situation, the present invention provides a high efficiency semiconductor device capable of effectively preventing short circuits of bonding wires, and a method to produce the same. The present invention also provides a semiconductor device capable of securing sufficient strength and fatigue resistance in and around the joint bulbs even when the sizes of the bonding materials and terminals are much reduced, and a method to produce the same. The gist of the present invention, which has been established to solve the above problems, is as follows:

(1) A semiconductor device, using a bonding material for linking a semiconductor terminal to a connecting terminal for an outside circuit, characterized by reinforcing the bonding material and/or a joint bulb between the terminal and a connecting material with a reinforcing material.

(2) A semiconductor device according to the item (1) characterized in that the bonding material is a bonding wire and/or a bump.

(3) A semiconductor device, using a bonding wire for linking a semiconductor terminal to a connecting terminal for an outside circuit, characterized by reinforcing the bonding wire, either partially or wholly, with a reinforcing material after bonding work.

(4) A semiconductor device according to any one of the items (1) to (3) characterized in that the bonding material and the reinforcing material consist of different materials.

(5) A semiconductor device according to any one of the items (1) to (4) characterized in that the reinforcing material consists of a metal and/or an inorganic material and the reinforcement covers the wire or a joint bulb with any of the metal coating and the inorganic material coating.

(6) A semiconductor device according to the item (5) characterized in that the metal coating consists of an alloy comprising one or more of nickel, copper, gold, tin, solder, silver, cobalt, chromium, platinum, palladium and tungsten.

(7) A semiconductor device according to any one of the items (1) to (6) characterized by forming, at the interface between the metal coating and the metal surface of the bonding wire, a diffusion layer of the two metals.

(8) A semiconductor device according to any one of the items (1) to (7) characterized in that the bonding wire consists of any one of gold, copper, aluminum, silver and an alloy of any of these metals.

(9) A semiconductor device according to any one of the items (1) to (8) characterized in that the concentration of gold at the outermost surface of a bonding wire consisting of gold or a gold alloy is 99% or less.

(10) A semiconductor device according to the item (1) characterized in that the bonding material consists of any one of gold, tin, copper, aluminum and an alloy of any of these metals.

(11) A semiconductor device according to any one of the items (1) to (10) characterized by coating the area covering the semiconductor, the bonding wires, the connecting terminals and the joint bulbs with resin.

(12) A semiconductor device according to the item (11) characterized in that the resin is a semiconductor sealing resin containing ceramic filler.

(13) A semiconductor device according to any one of the items (1) to (12) characterized by forming the connecting terminal using a substrate, a lead frame or a TAB tape.

(14) A semiconductor device according to any one of the items (1) to (13) characterized by forming the semiconductor terminal on any one of a semiconductor chip, the substrate, the lead frame or the TAB tape.

(15) A semiconductor device according to any one of items (1) to (14) characterized in that the surface of the semiconductor terminal consists of copper, aluminum, nickel, cobalt, gold, silver and an alloy of any of these metals.

(16) A method to produce a semiconductor device having a joint bulb between each of semiconductor terminals and connecting materials, characterized by including:

a process to bond the terminals with the bonding materials; and

another process to coat the connecting materials and/or the joint bulbs with a plating material for the purpose of reinforcement.

(17) A semiconductor device, using a bonding wire for linking a semiconductor terminal to a connecting terminal for an outside circuit, characterized by: the diameter of the bonding wire being less than 20 μm; and reinforcing the bonding wire, either partially or wholly, with a reinforcing material after bonding work.

(18) A method to produce a semiconductor device using a bonding wire for linking a semiconductor terminal to a connecting terminal for an outside circuit, characterized by including:

a process to link the semiconductor terminal with the connecting terminal using the bonding wire; and

a process to reinforce the bonding wire by coating it, either partially or wholly, with metal or inorganic material such as a ceramic.

(19) A method to produce a semiconductor device using a bonding wire for linking a semiconductor terminal to a connecting terminal for an outside circuit, characterized by including:

a process to link the semiconductor terminal with the connecting terminal using the bonding wire;

a process to reinforce the bonding wire by coating it, either partially or wholly, with a metal or an inorganic material such as a ceramic; and

a process to coat or seal the area, covering the semiconductor, the bonding wires and the connecting terminals, with resin.

(20) A method to produce a semiconductor device according to the item (18) or (19) characterized by coating the bonding wire, either partially or wholly, by electrolytic or electroless plating of metal in the process to reinforce the bonding wire.

(21) A method to produce a semiconductor device using a bonding wire for linking a semiconductor terminal to a connecting terminal for an outside circuit, according to any one of the items (16) to (20), characterized by including a process to subject the bonding wire to a heat treatment at a temperature of 50° C. or higher after the process to reinforce the wire by the metal coating.

By the present invention, it is possible to increase the diameter of a bonding wire by coating the wire in a specific portion with a reinforcing material after bonding work, thus increasing the wire strength. This prevents short circuits caused by the contact of a wire with another wire or a chip etc. as a result of the bending of the wires occurring during a process such as resin sealing after bonding work. This also prevents damage and breakage of a wire during the transportation of a semiconductor device after bonding work. Besides the above, the present invention prevents joint bulbs from reacting with additives in resin as well as oxygen and the humidity in the air, and copes with the stress building up at the bonding joints by coating at least the joint bulbs with a plating material after they are formed through the bonding of connecting materials onto terminals of the semiconductor device. Furthermore, the present invention prevents joint bulbs from the thermal stress by coating at least the joint bulbs with a plating material after they are formed through the bonding of bonding wires onto connecting terminals of the semiconductor device. For this reason, it is made possible to prevent the corrosion and contamination of a diffusion layer and a bonding material at a bonding joint and, as a consequence, improve the long-term reliability of a semiconductor device.

### DETAIL DESCRIPTION OF THE DRAWINGS

FIG. 1(a), 1(b) and 1(c) comprise illustrations of bonding joints according to embodiments of the present invention:

FIG. 1(a) shows a bonding joint between a semiconductor terminal and a bonding wire proper,

FIG. 1(b) shows a cross-sectional side view of FIG. 1(a), and

FIG. 1(c) a bonding joint between terminals of two semiconductors.

FIG. 2 is a schematic sectional view showing an example of the structure of a semiconductor device according to an embodiment of the present invention.

FIG. 3 is a perspective view of examples of lead frames related to an embodiment of the present invention in which lead frames the connecting terminals are formed.

FIG. 4(a) and 4(b) comprise illustrations showing a bonding process of chip terminals to connecting terminals and the condition after the bonding work according to an embodiment of the present invention.

FIG. 5(a) and 5(b) comprise schematic illustrations showing a coating process of a bonding material with a reinforcing material according to an embodiment of the present invention.

FIG. 6 is a schematic sectional view showing a resin sealing process according to an embodiment of the present invention.

FIG. 7 is a schematic sectional view showing an example of the semiconductor devices according to a modified embodiment of the present invention.

### DETAILED DESCRIPTION OF THE PREFERRED EMBODIMENT

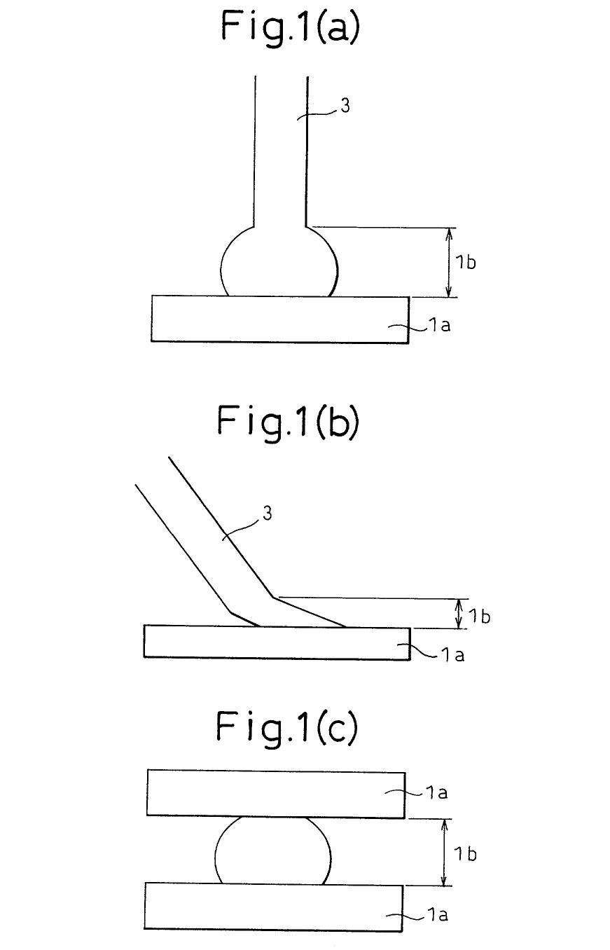

As conductive material consisting of Au, Cu, Al, Sn, etc. is used in the present invention as a connecting material in the form of a bonding wire or a bump and, in the use of the connecting material, it is linked to a semiconductor terminals consisting of Al, Cu, etc. At a bonding joint between a bonding wire and a semiconductor terminal where the bonding wire is used as the connecting material, a joint bulb 1b is formed between the bonding wire proper 3 and the semiconductor terminal 1a, as shown in FIG. 1(a). The joint bulb 1b made of the connecting material is formed through the deformation of the bonding wire during the bonding work. At a bonding joint between terminals 1a of two semiconductors using a bump as the connecting material, on the other hand, a joint bulb 1b is formed as shown in FIG. 1(b). Here, the joint bulb 1b of the connecting material is formed as a result of the deformation of the bump.

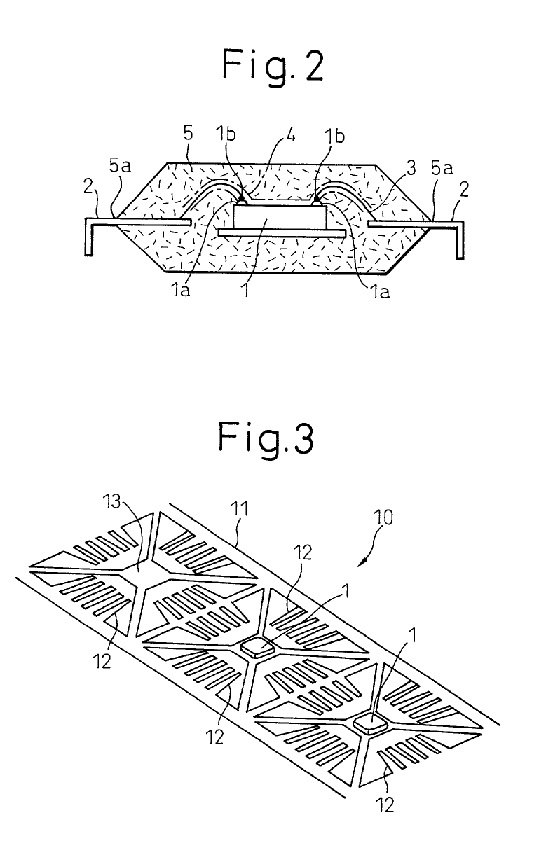

FIG. 2 shows an example of the structure of a semiconductor device. In the figure, a terminal 1a of a semiconductor chip 1 is linked to a connecting terminal 2 for an outside circuit by means of a bonding wire 3; the bonding wire 3 is reinforced, either partially or wholly, with a metal coating; and the area covering the semiconductor chip 1, the bonding wires 3 and the connecting terminals 2 is coated with resin 5.

Here, the connecting terminal 2 is formed as a part of a lead frame 10, as shown in FIG. 3. The lead frame 10 has many lead terminals 12 linked with tie bars 11, as seen in the example of the figure, and a semiconductor chip 1 is mounted and fixed on a pad 13 surrounded by the lead terminals 12. That is to say, the lead terminal 12 forms the connecting terminal 2.

The semiconductor chip 1 is of a square shape, for instance, 5 mm in each side and 208 chip terminals 1a are arranged on its upper surface along the periphery, and 208 lead terminals 12 are provided corresponding to the chip terminals 1a.

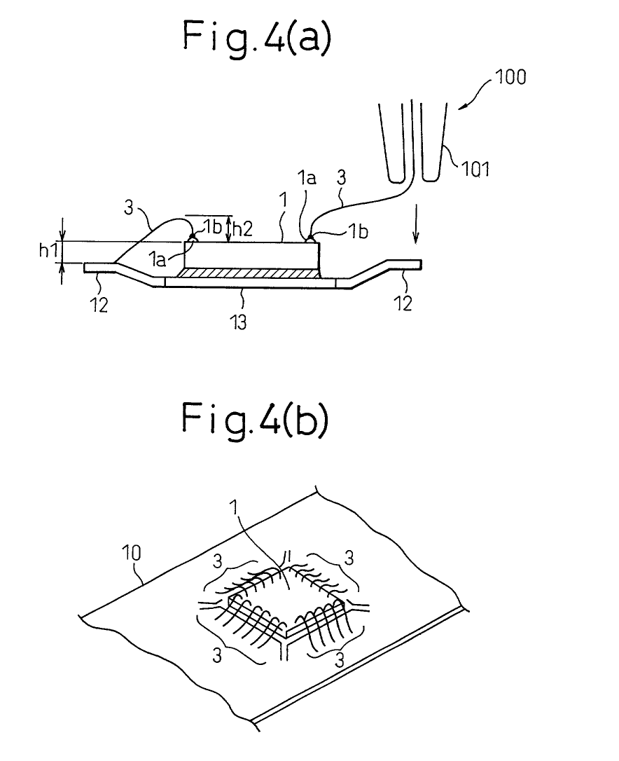

FIG. 4 shows a bonding process. A bonding wire 3 is first fed through a capillary 101 of a bonding machine 100 as seen in FIG. 4(a), bonded onto a chip terminal 1a (first side) of the semiconductor chip 1 by means of a joint bulb 1b formed in between and, then, bonded likewise onto a lead terminal 12 (second side) corresponding to the chip terminal 1a. The difference h1 between the upper surface of the semiconductor chip 1 and the bonding surface of the lead terminals 12 is 250 μm or so, the length of a bonding wire 3 after the bonding work is 6 mm, and the height h2 of a loop (upward curve) of the bonding wire from the upper surface of the semiconductor chip 1 is about 200 μm.

Metal coating is applied, for instance, by immersing the joint bulb and at least a part or whole of the wire in a plating liquid after bonding work. The coating metal is nickel, copper, tin, solder, silver, cobalt, chromium, platinum, palladium, or an alloy composed mainly of one of these metals or comprising at least one of them.

When a joint bulb 1b is coated with a plating material, the metal(s) composing the joint bulb is/are prevented from reacting with resin or Br and other additives contained in the resin after resin sealing. The coating also prevents the metal(s) from reacting with oxygen, humidity, etc. in the air, when the resin sealing is not applied. Besides, as fatigue often builds up in the joint bulbs, the coating of the joint bulbs with the plating material improves their tensile strength and Young's modulus and, thus, brings about an effect to enhance their fatigue resistance.

When both of a bonding wire and a joint bulb between a bonding wire and a connecting terminal are coated with a plating material, the joint bulb is prevented from the fracture due to the thermal stress induced by the heat flux from outside of the device even the joint temperature at the joint between a semiconductor device and a mother-board is increased by using the lead free solder.

Any of the above plating materials may be used as far as it can prevent the deterioration of the intermetallic compounds and diffusion layer formed at the bonding interface, but it is recommended to use any one of Cu, Ni, Co, Au, Pt and Pd or an alloy containing at least one of these metals. The above effect is obtained when the thickness of the coating material is 0.1 μm or more. If the thickness is 0.5 μm or more, fatigue resistance is further increased and, if it is 2 μm or more, yet higher corrosion resistance is obtained. A thickness below 0.1 μm, however, is not desirable, as the effect will be insufficient.

While there is no specific limitation with respect to the kind of a connecting material for obtaining the above effects, it is preferable to use any one of Au, Sn, Cu, Al or an alloy containing at least one of these metals, as the suitability of these materials has been proven through actual use. There is no specific limitation, either, with respect to the shape of a connecting material, but it is commonly used in the form of a bonding wire or a bump. There is no specific limitation also with respect to the material of terminals for obtaining the above effects, but the use of any of Al and an alloy containing Al for the terminals is preferable since they form a stable passive film on the surface to prevent excessive oxidation. When a material not forming a passive film on the surface such as Cu is used for the terminals, it is preferable to coat the surface of the terminals with any one of Ni, Cu and Au, or an alloy containing at least one of these metals, as the surface oxidation of the terminals is thus prevented. It is very advantageous to use: any one of Au, Sn, Cu and Al or an alloy containing at least one of these metals as the connecting material; any one of Cu, Al, Ni and Au or an alloy containing at least one of these metals as the surface material of the terminals; and any one of Cu, Ni, Co, Au, Pt and Pd or an alloy containing at least one of these metals as the plating material. Such material combinations bring about all the above effects at the same time.

Tangible effects are obtained when the thickness of a coating metal is at least 0.5% or so of a bonding wire diameter, but it is preferable if the thickness is 1% or more of a wire diameter. No specific upper limit is set with respect to the coating thickness unless any problem is expected in relation to a narrow bonding pitch between wires, but a preferable coating thickness is 50% or so of a wire diameter or less, because, with any thicker coating, homogeneous coating thickness cannot be formed easily by common coating methods such as plating. It is preferable that the strength or hardness of a coating metal is equal to that of a bonding wire or higher than it by 5% or more, or, more preferably, higher by 10% or more. However, with large diameter wires, tangible effects are obtained even if the strength or hardness of a coating metal is lower than that of a bonding wire. An effect to increase the strength near a coating interface can be obtained through the diffusion of a coating metal and a bonding wire metal. A heat treatment at 50° C. or higher is enough to accelerate the diffusion. A heat treatment at 100° C. or higher is preferable. A more preferable heat treatment condition is that the temperature is equal to or higher than ⅓ of the melting point of a bonding wire material or that of a coating metal, whichever the lower, in terms of absolute temperature. A preferable heat treatment temperature is 600° C. or below, since a heat treatment at a high temperature may adversely affect a semiconductor chip.

Either electrolytic plating or electroless plating may be employed for coating. It is preferable to selectively coat only wires, either partially or wholly, but, if metal parts, etc. other than the wires are plated, there will be no problem as far as the insulation between the terminals is maintained. If the exposure of a semiconductor surface to plating liquid or the like constitutes a problem, the portions other than the terminals may be protected by applying passivation films or the like or by coating with resin or a similar material. When resin coating is chosen for the purpose, liquid resin may be used, or a resin film having openings corresponding to the terminals may be applied to a semiconductor. As for the kind of resin, polyimide resin is suitable. In order to prevent lead frames and substrates from being coated, resin or a similar material may be applied selectively to the portions requiring protection, and then, after the coating work, removed using a solvent or the like, entirely or partially at the portions requiring its removal.

In either the electrolytic plating or the electroless plating, wire bonding portions can be selectively plated by holding a semiconductor device so that the wire bonding side may face downward, keeping the substrate surface or lead frame surface parallel to the plating liquid surface, and lowering it until only the lower surface of the substrate or that of the lead frame touches the plating liquid surface.

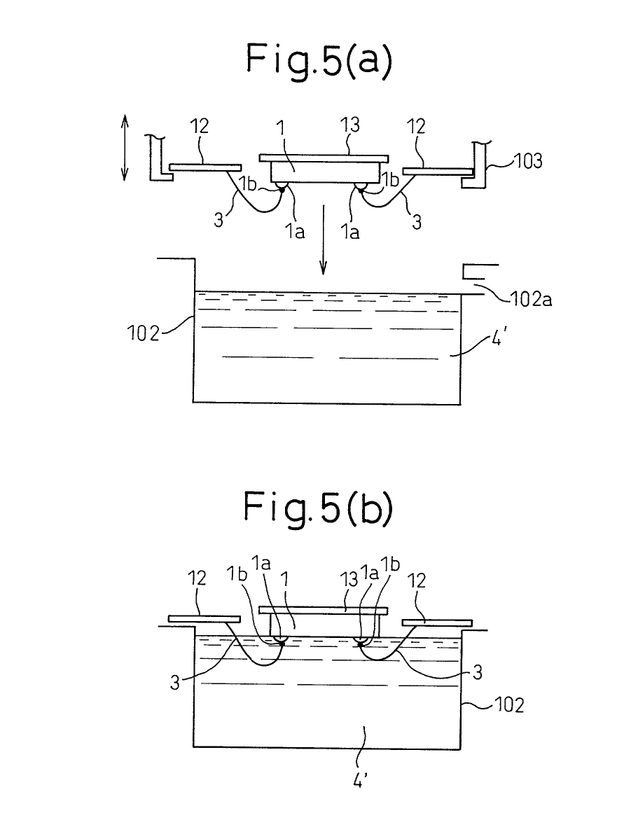

After the bonding work, the lead frame 10 on which the semiconductor chip 1 is mounted is turned upside down so as to have the bonding wires 3 face downward as shows in FIG. 5(a).

Then, the lead frame 10 is held horizontally above a plating liquid tank 102 containing a plating solution 4′ as seen in the figure. A vertically movable lifting device 103, provided above the plating liquid tank 102, to support the lead frame 10 at appropriate positions of its periphery can be used for the work. A plating liquid for nickel plating is used in this example. The plating liquid tank 102 has an overflow pipe 102a to keep the liquid surface level constant.

Next, the lead frame 10 is lowered by the lifting device 103, maintaining the horizontal position, namely keeping it parallel to the surface of the plating liquid 41, and the joint bulbs 1b and at least a part or the whole of the bonding wires 3 are immersed in the plating liquid as shown in FIG. 5(b). The lifting device 103 controls the height of the semiconductor chip 1 so that its upper surface (facing downward in FIG. 5(b)) may come in contact with the surface of the plating liquid 4′.

When the joint bulbs 1b and the bonding wires 3 are immersed in the plating liquid 4′, it is possible to control so that the lead terminals 12 may not be immersed in it, because, as can be understood from the example in the figure, the height, surface of the semiconductor chip 1 and that of the lead terminals 12 are different by the difference h1.

When electroless plating is employed for the wire reinforcement, ions of the coating metal and a reducing agent coexist in the plating liquid and, in addition, a complexing agent, a buffer agent, a stabilizing agent, etc. are also contained as required. A suitable reducing agent is: phosphinic acid sodium, dimethylamine borane, hydrazine, potassium tetrahydroborade, etc. for Ni or Co plating; dimethylamine borane, potassium tetrahydroborade, etc. for Au or Ag plating; phosphinic acid sodium, sodium phosphonate potassium tetrahydroborade, etc. for palladium plating; formalin, dimethylamine borane, or potassium tetrahydroborade for Cu plating; titanium trichloride, etc. for Sn plating; and hydrazine, sodium tetrahydroborade, etc. for Pt plating. The use of a Ni—P or Ni—B alloy or the like is good for obtaining good strength by Ni plating: an alloy with P or B in a concentration from 0.05 to 20% brings about a remarkable effect to increase strength. The most suitable concentration range is from 0.1 to 15%. If the concentration of P or B exceeds 20%, it becomes difficult to keep the composition of the plating alloy homogeneous.

When electrolytic plating is employed, a method to plate in a plating liquid bath by negatively energizing the portions linked with wires or a method of selective plating such as brush plating may be used. When a lead frame is used in a semiconductor device, in usual cases, all the connecting terminals are electrically linked with each other via a lead frame metal after wire bonding work and, thus, all the wires can be negatively energized if any one point of these parts is linked with a negative pole. It is preferable that the energizing voltage does not exceed the withstand voltage of the semiconductor chip, and it has to be set at, for example, 5 V or lower.

Any one of the metals usable for plating such as gold, copper, nickel, palladium, tungsten, cobalt and chromium or an alloy of these metals may be used for electrolytic plating.

When wires are reinforced by the coating of an inorganic material such as ceramics or glass, the sol-gel method, for instance, is suitable: in this method, the wires are immersed, at least partially, in a solution of sol to form a film of the sol on the wire surface, the film is dried in a gas or air to turn the sol into gel, and then the gel is hardened by means of heating at a temperature of about 100° C. or higher. Films of oxides such as silica, alumina, titania, barium titanate, niobium oxide, iron oxide, etc. 2 μm or less in thickness can be thus formed stably. A tangible reinforcing effect is obtained when the film is 0.03 μm or more in thickness. It is also possible to form an organic/inorganic hybrid film and, in this case, it is possible to obtain a thickness of 2 μm or more.

When wires are heated after reinforcing coating with a film of oxides, compounds, etc., diffusion takes place between the film and the metal material of the wires, which increases strength of the interface through the formation of an alloy film. A heat treatment at 50° C. or higher will accelerate the diffusion. A heat treatment at 100° C. or higher is preferable. A more preferable heat treatment condition is that the temperature is equal to or higher than ⅓ of the melting point of a joint bulb, that of a bonding wire material or that of a coating material, whichever is the lowest, in terms of absolute temperature. A preferable heat treatment temperature is 600° C. or below, since a heat treatment at a high temperature may adversely affect the semiconductor chip.

It is also effective to form multiple coating layers by combining two or more different coatings of metal, ceramics, inorganic and organic/inorganic hybrid materials. A preferable multiple layer structure is that, for example, when a bonding wire is of gold or copper, a coating material having good adhesion with the bonding wire material, such as nickel, gold, copper or an alloy of any one of these metals, is used for an inner layer, and a material excellent in corrosion resistance, strength and adhesion with sealing resin, such as nickel or chromium, is used for an outer layer. An insulating material such as resin or ceramics may well be used for the outermost coating layer.

As for a bonding wire material, while gold is generally used as the mainstream material and aluminum and copper are used sometimes, other metals are seldom used for bonding wires owing to problems such as insufficient corrosion resistance, bondability, and reliability of bonding joints.

Bonding wires of silver, aluminum or copper can be reinforced and rendered corrosion-resistant at the same time by coating them with a material such as gold, palladium, nickel or chromium after bonding work. Gold wires may sometimes develop corrosion especially at grain boundaries, etc. at the wire surface, as a result of alloying elements segregating at the surface. Coating with a reinforcing metal having high corrosion resistance is effective for checking the progress of such local corrosion of gold wires and similar problems. In addition, when a noble metal such as gold is used for the bonding wire and the coating is applied by electroless plating, it is effective to have a different element or different elements exist at the gold surface as electron supply sources at the initial stage of the plating. A preferable concentration of the element(s) is 0.5% or higher, and it is most preferable if the concentration is 1% or higher. Cu, Be, Ca, Pd, Ag, Pb, Mn, Zn, Sn, a rare earth element, etc. can be used as the addition element(s), and it/they may be added to the gold in a very small quantity and made to segregate at the surface. The concentration of the element(s) at the surface can be measured by methods such as the Auger electron spectroscopy.

The diameter of the generally used bonding wires is from 23 to 30 μm or so. When the diameter is smaller than this, the wires may bend during a resin sealing process after bonding work, causing short circuits, wire breakage, etc. The reinforcement of wires makes it possible to use bonding wires thinner than 20 μm, hitherto difficult to use industrially, such as a gold bonding wire 17 μm in diameter. The application of a Ni plating 1 μm in thickness on gold bonding wires 17 μm in diameter after bonding work reduces resin-flow-induced wire deformation during resin sealing to less than that of 23-μm diameter gold bonding wires. This not only decreases the material cost of the gold wires, but also increases the conductivity by the metal coating, making up for the increased electric resistance of the thinner wire. When the plating work covers the bonding joints of the wires, the joint bulbs are also reinforced at the same time. When reinforcing bonding joints with the terminals of aluminum on the ball bonding side, a plating method applicable to aluminum materials can be selected. Joint bulbs between wires and semiconductor terminals of aluminum can be reinforced, for instance, by plating the terminals with Ni after substitution of aluminum surface with Zn.

In the case that a chip is coated with resin or it is resin-sealed after bonding work, the adhesion of the resin can be improved and the reliability of the resin packaging can be enhanced by properly choosing the material of the reinforcing coating.

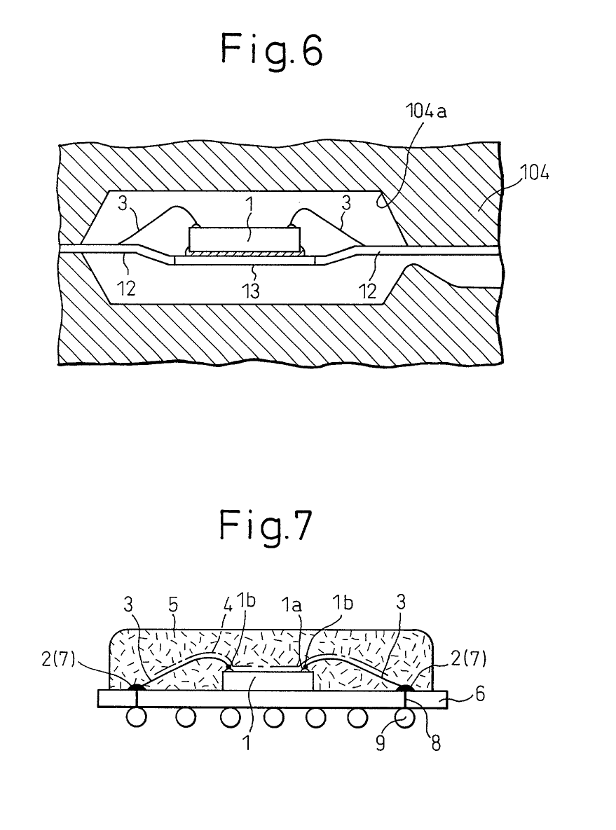

When a lead frame is used, the semiconductor chip 1 mounted on the lead frame 10 is set, after reinforcing coating, in a cavity 104a of a forming mold 104, as shown in FIG. 6. A resin-molded semiconductor device as shown in FIG. 2 is obtained by injecting a solution of resin 5 into the cavity 104a and removing the mold 104 after a prescribed time.

The adhesion of a sealing resin to a substrate can be improved and the leakage of the resin during its injection and other problems can be avoided, even when a conventional mold is used, by applying metal coating to cover bonding wires only or bonding wires and joint bulbs. Even when metal parts such as lead frames are coated by plating or the like at the same time as bonding wires are coated, the device can be conventionally resin-sealed, as long as the thickness of the reinforcing coating material is smaller than a certain value. For this end, it is preferable that the coating thickness is 5 μm or less. A potting compound or epoxy resin containing ceramic filler is suitable as a sealing resin.

When bonding wires are made of gold and semiconductor terminals are made of aluminum, diffusion sometimes proceeds excessively, deteriorating the reliability of bonding joints. For this reason, unless the bonding joints are structurally reinforced, it is important that, in the processes such as drying and heating after sol-gel coating, the diffusion heat treatment of metal coating, resin coating, or resin sealing, the relation between the temperature T (° C.) and the time t (sec.) satisfies the condition given in expression (1), in order to secure sufficient adhesion of the coating after the bonding work.

15,000×\sqrt{t}exp{−5,100/(273+T)}<1 (1)

As explained above, when producing a semiconductor device according to the present invention, a specified part of a bonding wire 3 has to be coated with a reinforcing material before resin sealing. This decreases the resin-flow-induced deformation of the bonding wires 3 during the resin sealing, especially during the injection of the solution of the resin 5 into the cavity 104a and, therefore, prevents short circuits from occurring between two bonding wires 3, between a bonding wire 3 and the chip or other part.

A modification of the present invention is explained hereinafter. While an example of forming connecting terminals 2 for outside circuits using a lead frame 10 was explained in the above embodiment, the present invention can also be applied to a semiconductor device (such as a ball grid array (BGA), etc.) structured as shown in FIG. 7.

In FIG. 7, a connecting terminal 2 for an outside circuit consists of a terminal 7 formed on a substrate 6 composed of glass epoxy, etc. A chip terminal 1a of a semiconductor chip 1 is linked to the terminal 7 via a bonding wire 3, and the terminal 7 is linked to a conductive metal ball 9 on the other side of the substrate 6 by means of a conductor 8 formed through a hole drilled across the substrate 6.

In this example, too, the bonding wire 3 is coated, at least partially or wholly, with a first resin 4 (shown with chain lines) for reinforcement, and the area covering the semiconductor chip 1, the bonding wires 3 and the connecting terminals 2 (terminals 7) is coated with a second resin 5 for insulation. The short circuits of the bonding wires 3 can be prevented, as in the embodiment described before, by reinforcing the bonding wires 3 by coating them in prescribed portions.

The preferred embodiments of the present invention have been explained above. The present invention, however, is not limited to the embodiments explained above, but various modifications are possible within the scope of the present invention.

The present invention is applicable, like the above embodiments, to a semiconductor device using a polyimide film as a substrate and having connecting terminals on the substrate, for example. Further, specific figures and other details included in the explanations of the above embodiments may be modified depending on conditions, and effects similar to those obtained in the above embodiments can be enjoyed.

For plating joint bulbs only, a method such as an electrolytic plating method using a brush is applicable. This is a method to selectively plate a joint bulb by imposing a voltage on a brush impregnated with a plating liquid at its tip and also the joint bulb to be coated, while the brush is held in contact with the bulb. The size of the brush tip has to be approximately the same as the joint bulbs, and it is preferable that the voltage to be imposed is equal to or less than the withstand voltage of the chip: 5 V or less is suitable.

Another method to plate joint bulbs only is to apply, before the plating work, a masking material to the areas not to be coated with the plating material. By this method, only the areas requiring the coating can be selectively plated by: applying, before the plating work, a masking material to the areas not to be coated with the plating material such as the areas other than the bonding joints; plating the chip with the plating material thereafter; and, then, removing the masking material using an organic solvent after the plating work. An organic Si material or the like is suitable as the masking material and it can be applied by means of spraying or a method to use a brush. Acetone, ethyl alcohol, etc. can be used as an organic solvent to remove the masking material.

Additionally, by the present invention, adhesion between the joint bulb and the plating material can be enhanced by forming a diffusion layer between the joint bulb and the plating material coating the joint bulb. In this case, the increased adhesion brings about an effect to remarkably improve fatigue resistance, in addition to the effects of the present invention. The present invention does not specify the method to form the diffusion layer. Heating the bonding joints after the coating, for instance, is effective for the purpose. It is preferable that the heating temperature is lower than the lowest of the melting points of the materials composing the bonding joint. A thermostatic oven, an electric oven, an image oven or the like may be used for the heating. No specifically controlled atmosphere is required for the heating. An atmosphere of 0.01 atm or lower or an inert gas atmosphere, for instance, is desirable since the oxidation of the materials can be minimized.

A coating according to the present invention can be formed in two or more layers. By doing so, the effect of a coating material to seal joint bulbs is increased and, thus, the corrosion resistance of the joint bulbs is remarkably improved in addition to the effects of the present invention. Even when a plating material highly corrosion-resistant but not so highly adhesive to the joint bulbs is to be used, for instance, improved adhesion between the plating material and the joint bulbs can be obtained in addition to the high corrosion resistance of the joint bulbs and, hence, a significant increase in fatigue resistance is realized by the use of a material highly adhesive to the joint bulbs for the first layer plating and the highly corrosion-resistant plating material for the second coating layer. A multiple-layer coating can be made by forming the first layer by any of the methods to form a coating layer explained before, and the second and subsequent layers likewise over the first layer.

### EXAMPLE 1

Each of the samples used herein was prepared as follows. A semiconductor chip 1 was fixed on a die pad 13 of a lead frame, and chip terminals 1a of the semiconductor were linked to corresponding lead terminals 12 of the lead frame 10 using gold bonding wires as shown in FIG. 3. Here, 200 pieces of chip terminals were arranged on the chip along the sides at a 60-μm pitch, and the average length of the wires was about 5 mm. The lead frame was made of an Fe-42%Ni alloy and their leads were plated with silver. The gold bonding wires had a purity of 99.9% or higher and contained 10 ppm or more in total of one or more of Ca, Cu, Pd and a rare earth element as alloying element(s). As a result of composition analyses at the outermost surfaces of the gold wires, the gold concentration there was found to be 98% or less, and C and other impurity elements were detected. The terminals of the sample chips were bonded with bonding wires 14, 17, 23, 25 and 27 μm in diameter, and then the wires were coated with Ni by immersing the entire lead frame in an electroless Ni-plating bath containing phosphinic acid sodium as a reducing agent. The die bonding material of the chip was formed so that its metal content might not be exposed at the surfaces contacting the plating liquid, and it was confirmed that the die bonding material was not damaged in the plating bath. The thickness of the reinforcing coating was controlled to 0.1, 0.2, 0.5, 1, 2 and 3 μm. A sealing resin containing ceramic filler was used for the resin sealing, and the wire deformation and electrical contact between wires were examined. A sample chip with an average wire deformation less than 2% was classified as A, that with an average wire deformation of 3% or more but less than 5% as B, and that with an average wire deformation 5% or more as C. Sample chips without the reinforcing coating were also prepared for comparison purposes. The electrical contact was tested by measuring electrical conduction between wires. If electrical conduction was detected between two adjacent wires among the 200 wires of a chip, the chip was classified as poor, marked with ×, and a chip without such electrical conduction as good, marked with ∘. The results are listed in Table 1.

TABLE 1

| | | Wire | Coating | | |
|---|---|---|---|---|---|
| | | diameter | thickness | Wire | Electric |
| | No. | μm | μm | deformation | conduction |
| Inventive | 1 | 14 | 1 | B | ∘ |
| sample | | | | | |
| Inventive | 2 | 14 | 3 | A | ∘ |
| sample | | | | | |
| Inventive | 3 | 17 | 0.5 | A | ∘ |
| sample | | | | | |
| Inventive | 4 | 17 | 0.2 | B | ∘ |
| sample | | | | | |
| Inventive | 5 | 23 | 0.2 | A | ∘ |
| sample | | | | | |
| Inventive | 6 | 23 | 2 | A | ∘ |
| sample | | | | | |
| Inventive | 7 | 25 | 0.1 | B | ∘ |
| sample | | | | | |
| Inventive | 8 | 25 | 0.5 | A | ∘ |
| sample | | | | | |
| Comparative | 9 | 25 | 0 | C | x |
| sample | | | | | |
| Comparative | 10 | 27 | 0 | B | ∘ |
| sample | | | | | |

Any of the inventive samples Nos. 1 to 8 of this Example 1 showed no electrical conduction between wires and a small degrees of wire deformation as a result of the resin sealing. The comparative sample No. 9 exhibited electrical conduction between wires and large wire deformation. Although the comparative sample No. 10 showed no electrical conduction between wires, the diameter of the balls formed at the end of the wires was large, threatening to touch adjacent balls when linked to the terminals on the semiconductor chip by ball bonding, because of thick bonding wires 27 μm in diameter used therein. The material cost of the gold of the 27-μm diameter wire was 2.5 times that of the 17-μm diameter wire or more.

Some other sample chips were bonded using bonding wires 23 μm in diameter containing 5% or less of alloying elements. The wires bent and sagged significantly immediately after the bonding work and all these chips were classified as C in the wire deformation test.

### EXAMPLE 2

Each of the sample semiconductor chips was fixed on a lead frame, and the chip terminals were linked to corresponding leads with bonding wires, in the same manner as in Example 1. Aluminum, copper and gold were used for plating the surface of the terminals of the chips used in this example, and only one of the metals was used for plating the terminals of each of the chips. Bonding wires of gold, silver and copper were used and the diameter of all the wires was 23 μm. Sample chips were electrolytically plated in a metal plating bath, some with one material and others with two materials, to obtain a coating thickness of 0.5 to 0.7 μm in total in either case. The wires were negatively energized through the lead frame. The wires were plated by immersing them in the plating bath, as shown in FIG. 5, up to the portions immediately below the surface of the lead frame.

After the resin sealing, the wire deformation was measured. A sample in which the wire deformation was improved from the deformation of wires without the reinforcing coating by 10% or more was classified as A, that with an improvement by 5% or more as B, and that with an improvement by 5% or less as C. The results are listed in Table 2. The note “Heated” in the column “Plating metal” indicates a sample heated to 200° C. for 30 min. after the plating.

TABLE 2

| | | Terminal | Wire | Plating | Wire |
|---|---|---|---|---|---|
| | No. | material | material | metal | deformation |
| Inventive | 21 | Al | Au | Cu | B |
| sample | | | | | |
| Inventive | 22 | Cu | Au | Cu/Heated | A |
| sample | | | | | |
| Inventive | 23 | Al | Au | Ni | A |
| sample | | | | | |
| Inventive | 24 | Al | Cu | Pd/Ni | A |
| sample | | | | | |
| Inventive | 25 | Cu | Ag | Ag/Heated | B |
| sample | | | | | |
| Inventive | 26 | Al | Au | Sn | B |
| sample | | | | | |
| Inventive | 27 | Au | Au | Pd | A |
| sample | | | | | |
| Inventive | 28 | Al | Au | Pt | A |
| sample | | | | | |
| Inventive | 29 | Al | Au | Sn/Heated | A |
| sample | | | | | |
| Inventive | 30 | Al | Au | Cr | A |
| sample | | | | | |

Pull tests of the wires were also carried out before and after the reinforcing coating. As a result, the pull strength of any of the samples was found to have increased after the coating, and the samples having undergone the heating process showed more homogeneous strength than those without the heating. The pull strength and wire deformation of the samples using gold wires plated with Sn were remarkably improved after the heating process.

### EXAMPLE 3

For the purpose of investigating the effects of the present invention on the long-term reliability of the bonding joints, the tests described below were carried out on the sample chips packaged using bonding wires and those packaged using bumps. In each of the sample chips packaged with bonding wires, a semiconductor chip of Si was fixed on a lead frame, and the chip terminals were linked to corresponding lead terminals of the lead frame using connecting materials in the form of wire 20 μm in diameter, in the same manner as in Examples 1 and 2. Here, 200 pieces of chip terminals were arranged on the surface of a chip along the sides at a 60-μm pitch, and the average length of the wires was 5 mm. The lead frames were made of an Fe-42%Ni alloy (in mass %) and their leads were plated with Ag. The connecting material was a bonding wire mainly composed of Au, containing 10 ppm (in mass) or more in total of one or more of Ca, Cu, Pd and a rare earth element.

After the bonding work, the entire lead frame was immersed in a plating bath for the purpose of coating the joint bulbs and the bonding wires by electroless plating.

Some samples underwent a process to form a second layer coating as specified in sample No. 59 of Table 3 by the same method as the above first coating layer. The thickness of the inner and outer layers were 0.05 μm, respectively.

Some samples were heated after the coating of the first layer to form a diffusion layer between the wire and the first coating layer. The heating was done by keeping the samples for 20 h. in an electric oven kept at 400° C., as specified in sample No. 60 of Table 3. The thickness of the coating layer before heating was 0.10 μm, and the thickness of the inner and outer layers were 0.01 μm and 0.09 μm, respectively.

TABLE 3

| | | | | | | | | | | | Test 3: Pulse heating test | | | | | |
|---|---|---|---|---|---|---|---|---|---|---|---|---|---|---|---|---|
| | | | | | | | | | | | 200° C. 200 h | | 200° C. 250 h | | 200° C. 300 h | |
| | | | | | Test 1: Accelerated | | | Test 2: Thermal | | | Side of | | Side of | | Side of | |
| | | | | Plating | heating test | | | cycle test | | | semi- | Side of | semi- | Side of | semi- | Side of |
| | | Con- | Coating | thick- | 200° | 200° | 200° | 1000 | 1250 | 1500 | con- | con- | con- | con- | con- | con- |
| | | necting | layer | ness | C. | C. | C. | cy- | cy- | cy- | ductor | necting | ductor | necting | ductor | necting |
| | | material | composition | μm | 200 h | 250 h | 300 h | cles | cles | cles | terminal | terminal | terminal | terminal | terminal | terminal |
| Inventive | 41 | Wire | Ni-10 mass | 0.10 | ∘ | x | x | ∘ | x | x | ∘ | ∘ | x | x | x | x |
| sample | | | % P | | | | | | | | | | | | | |
| Inventive | 42 | Wire | Ni-10 mass | 0.50 | ∘ | ∘ | x | ∘ | ∘ | x | ∘ | ∘ | ∘ | ∘ | x | x |
| sample | | | % P | | | | | | | | | | | | | |
| Inventive | 43 | Wire | Ni-10 mass | 2.00 | ∘ | ∘ | ∘ | ∘ | ∘ | ∘ | ∘ | ∘ | ∘ | ∘ | ∘ | ∘ |
| sample | | | % P | | | | | | | | | | | | | |
| Inventive | 44 | Wire | Co-3 mass | 0.10 | ∘ | x | x | ∘ | x | x | ∘ | ∘ | x | x | x | x |
| sample | | | % P | | | | | | | | | | | | | |
| Inventive | 45 | Wire | Co-3 mass | 0.50 | ∘ | ∘ | x | ∘ | ∘ | x | ∘ | ∘ | ∘ | ∘ | x | x |
| sample | | | % P | | | | | | | | | | | | | |
| Inventive | 46 | Wire | Co-3 mass | 2.00 | ∘ | ∘ | ∘ | ∘ | ∘ | ∘ | ∘ | ∘ | ∘ | ∘ | ∘ | ∘ |
| sample | | | % P | | | | | | | | | | | | | |
| Inventive | 47 | Wire | Pd-5 mass | 0.10 | ∘ | x | x | ∘ | x | x | ∘ | ∘ | x | x | x | x |
| sample | | | % Na | | | | | | | | | | | | | |
| Inventive | 48 | Wire | Pd-5 mass | 0.50 | ∘ | ∘ | x | ∘ | ∘ | x | ∘ | ∘ | ∘ | ∘ | x | x |
| sample | | | % Na | | | | | | | | | | | | | |
| Inventive | 49 | Wire | Pd-5 mass | 2.00 | ∘ | ∘ | ∘ | ∘ | ∘ | ∘ | ∘ | ∘ | ∘ | ∘ | ∘ | ∘ |
| sample | | | % Na | | | | | | | | | | | | | |
| Inventive | 50 | Wire | Au-5 mass | 0.10 | ∘ | x | x | ∘ | x | x | ∘ | ∘ | x | x | x | x |
| sample | | | % K | | | | | | | | | | | | | |
| Inventive | 51 | Wire | Au-5 mass | 0.50 | ∘ | ∘ | x | ∘ | ∘ | x | ∘ | ∘ | ∘ | ∘ | x | x |
| sample | | | % K | | | | | | | | | | | | | |
| Inventive | 52 | Wire | Au-5 mass | 2.00 | ∘ | ∘ | ∘ | ∘ | ∘ | ∘ | ∘ | ∘ | ∘ | ∘ | ∘ | ∘ |
| sample | | | % K | | | | | | | | | | | | | |
| Inventive | 53 | Wire | Pt | 0.10 | ∘ | x | x | ∘ | x | x | ∘ | ∘ | x | x | x | x |
| sample | | | | | | | | | | | | | | | | |
| Inventive | 54 | Wire | Pt | 0.50 | ∘ | ∘ | x | ∘ | ∘ | x | ∘ | ∘ | ∘ | ∘ | x | x |
| sample | | | | | | | | | | | | | | | | |
| Inventive | 55 | Wire | Pt | 2.00 | ∘ | ∘ | ∘ | ∘ | ∘ | ∘ | ∘ | ∘ | ∘ | ∘ | ∘ | ∘ |
| sample | | | | | | | | | | | | | | | | |
| Inventive | 56 | Wire | Cu-5 mass | 0.10 | ∘ | x | x | ∘ | x | x | ∘ | ∘ | x | x | x | x |
| sample | | | % Na | | | | | | | | | | | | | |
| Inventive | 57 | Wire | Cu-5 mass | 0.50 | ∘ | ∘ | x | ∘ | ∘ | x | ∘ | ∘ | ∘ | ∘ | x | x |
| sample | | | % Na | | | | | | | | | | | | | |
| Inventive | 58 | Wire | Cu-5 mass | 2.00 | ∘ | ∘ | ∘ | ∘ | ∘ | ∘ | ∘ | ∘ | ∘ | ∘ | ∘ | ∘ |
| sample | | | % Na | | | | | | | | | | | | | |
| Inventive | 59 | Wire | Inner layer | 0.10 | ∘ | ∘ | x | ∘ | x | x | ∘ | ∘ | ∘ | ∘ | x | x |
| sample | | | Cu-5 mass | | | | | | | | | | | | | |
| | | | % Na, | | | | | | | | | | | | | |
| | | | Outer layer | | | | | | | | | | | | | |
| | | | Ni-10 mass | | | | | | | | | | | | | |
| | | | % P | | | | | | | | | | | | | |
| Inventive | 60 | Wire | Inner layer | 0.10 | ∘ | x | x | ∘ | ∘ | x | ∘ | ∘ | x | x | x | x |
| sample | | | Au—Co, | | | | | | | | | | | | | |
| | | | Outer layer | | | | | | | | | | | | | |
| | | | Co-3 mass | | | | | | | | | | | | | |
| | | | % P | | | | | | | | | | | | | |
| Inventive | 61 | Bump | Cu-5 mass | 0.10 | ∘ | x | x | ∘ | x | x | ∘ | ∘ | x | x | x | x |
| sample | | | % Na | | | | | | | | | | | | | |
| Compara- | 62 | Wire | nil | 0 | x | x | x | x | x | x | x | x | x | x | x | x |
| tive | | | | | | | | | | | | | | | | |
| sample | | | | | | | | | | | | | | | | |
| Compara- | 63 | Bump | nil | 0 | x | x | x | x | x | x | x | x | x | x | x | x |
| tive | | | | | | | | | | | | | | | | |
| sample | | | | | | | | | | | | | | | | |

In the case of a sample packaged using bumps, the substrate was made of a glass epoxy resin and had a square shape 4 cm in each side. 200 pieces of first terminals made of aluminum were formed on the substrate, and then bumps were formed, following a ball bump method, by bonding Au balls 80 μm in diameter onto the first terminals by thermocompression bonding. A substrate thus prepared was held face to face with a semiconductor chip consisting of Si having a square shape 1 cm in each side, in a manner that the bumps of the substrate contact corresponding second terminals made of Al formed on the semiconductor chip surface and, finally, the substrate and the chip were pressed against each other to bond together by thermocompression bonding, with the bumps in between.

After forming the bumps, the whole sample was immersed in a plating bath to coat the bonding joints and bumps by electroless plating.

The compositions of the coating layers of the samples were identified by polishing a sectional surface of a bonding joint after the plating and analyzing the surface by EDX. The thickness of the coating layer was measured through SEM observation of a sectional surface.

The following two tests were carried out on the samples thus prepared:

(Test 1)

Sample packages were prepared by sealing the semiconductor chips with sealing resin containing ceramic filler after the plating process.

The packages thus formed underwent an accelerated heating by keeping them in an electric oven at 200° C. for 200 h., which is the heating condition commonly used for testing the corrosion resistance of semiconductor devices, and a sample was evaluated as good with respect to corrosion resistance, if no corrosion product was observed at sectional observations of bonding joints after the accelerated heating.

In addition to the above, the accelerated heating test was extended to yet more severe conditions of 250° C. and 300 h.

The results are shown in Table 3, in which ∘ means that the sample passed the test.

Good corrosion resistance was obtained in any of the invention samples Nos. 41 to 61. In the extended severe tests for differentiating the samples, the invention samples Nos. 42, 45, 48, 51, 54, 57 and 59 showed good corrosion resistance after the severe accelerated heating test at 200° C. for 250 h., and the invention samples Nos. 43, 46, 49, 52, 55 and 58 showed extremely good corrosion resistance withstanding the yet more severe accelerated heating test at 200° C. for 300 h. The invention sample No. 60, which had two coating layers, showed extremely high corrosion resistance despite its thin plating thickness of 0.10 μm.

In contrast, corrosion resistance was poor in the comparative samples in which the bonding wires were not plated.

(Test 2)

The coated samples underwent 1,000 cycles of thermal cycle test (TCT) from −40° C.×30 min. to +125° C.×30 min., which is the condition commonly used for testing fatigue resistance of semiconductor devices, and a sample was evaluated as good with respect to fatigue resistance if a pull strength of 8 gf or higher was confirmed in a pull strength test of bonding joints after the TCT.

In addition to the above, the TCT was extended to 1,250 and 1,500 cycles. The results are shown in Table 3, in which ∘ means that the sample passed the test.

Good fatigue resistance was obtained in any of the invention samples Nos. 41 to 61. In the extended more severe tests for differentiating the samples, the invention samples Nos. 42, 45, 48, 51, 54, 57 and 59 showed good fatigue resistance after the severer TCT of 1,250 cycles, and the invention samples Nos. 43, 46, 49, 52, 55 and 58 showed extremely good fatigue resistance withstanding the yet more severe TCT of 1,500 cycles. The invention sample No. 60, which had a diffusion layer between the wire and the coating layer, showed extremely high fatigue resistance despite its thin plating thickness of 0.10 μm.

In contrast, fatigue resistance was poor in the comparative samples in which the wires were not plated.

(Test 3)

Sample packages were prepared by sealing the semiconductor chips with sealing resin containing ceramic filler after the plating process.

The packages thus formed underwent an pulse heating by keeping them in an electric oven at 280° C. for 10 minutes, which is the heating condition commonly used for jointing a device and a mother board, and a sample was evaluated as good with respect to fracture resistance, if no crack was observed at SEM (Scanning Electron Microscope) observations of joints between a bonding wire and a connecting terminal after the pulse heating.

In addition to the above, the pulse heating test was extended to yet more severe condition of 330° C.

The results are shown in Table 3, in which ∘ means that the sample passed the test.

Good fracture resistance was obtained in any of the invention samples Nos. 41 to 61. In the extended severe test for differentiating the samples, the invention samples Nos. 42, 45, 48, 51, 54, 57 and 59 showed good fracture resistance after the severe pulse heating test at 330° C.

In contrast, fracture resistance was poor in the comparative sample in which the bonding wire was not plated.

1. A semiconductor device, using a bonding material for linking a semiconductor terminal to a connecting terminal for an outside circuit, characterized by reinforcing the bonding material and/or a joint bulb between the terminal and a connecting material with a reinforcing material.

2. A semiconductor device according to claim 1 characterized in that the bonding material is a bonding wire and/or a bump.

3. A semiconductor device, using a bonding wire for linking a semiconductor terminal to a connecting terminal for an outside circuit, characterized by reinforcing the bonding wire, either partially or wholly, with a reinforcing material after bonding work.

4. A semiconductor device according to any one of claims 1 to 3 characterized in that the bonding material and the reinforcing material consist of different materials.

5. A semiconductor device according to any one of claims 1 to 4 characterized in that the reinforcing material consists of a metal and/or an inorganic material and the reinforcement covers the wire or a joint bulb with any of the metal coating and the inorganic material coating.

6. A semiconductor device according to claim 5 characterized in that the metal coating consists of an alloy comprising one or more of nickel, copper, gold, tin, solder, silver, cobalt, chromium, platinum, palladium and tungsten.

7. A semiconductor device according to any one of claims 1 to 6 characterized by forming, at the interface between the metal coating and the metal surface of the bonding wire, a diffusion layer of the two metals.

8. A semiconductor device according to any one of claims 1 to 7 characterized in that the bonding wire consists of any one of gold, copper, aluminum, silver and an alloy of any of these metals.

9. A semiconductor device according to any one of claims 1 to 8 characterized in that the concentration of gold at the outermost surface of a bonding wire consisting of gold or a gold alloy is 99% or less.

10. A semiconductor device according to claim 1 characterized in that the bonding material consists of any one of gold, tin, copper, aluminum and an alloy of any of these metals.

11. A semiconductor device according to any one of claims 1 to 10 characterized by coating the area covering the semiconductor, the bonding wires, the connecting terminals and the joint bulbs with resin.

12. A semiconductor device according to claim 11 characterized in that the resin is a semiconductor sealing resin containing ceramic filler.

13. A semiconductor device according to any one of claims 1 to 12 characterized by forming the connecting terminal using a substrate, a lead frame or a TAB tape.

14. A semiconductor device according to any one of claims 1 to 13 characterized by forming the semiconductor terminal on any one of a semiconductor chip, the substrate, the lead frame or the TAB tape.

15. A semiconductor device according to any one of claims 1 to 14 characterized in that the surface of the semiconductor terminal consists of copper, aluminum, nickel, cobalt, gold, silver and an alloy of any of these metals.

16. A method to produce a semiconductor device having a joint bulb between each of semiconductor terminals and connecting materials, characterized by including:
a process to bond the terminals with the bonding materials; and
another process to coat the connecting materials and/or the joint bulbs with a plating material for the purpose of reinforcement.

17. A semiconductor device, using a bonding wire for linking a semiconductor terminal to a connecting terminal for an outside circuit, characterized by: the diameter of the bonding wire being less than 20 μm; and reinforcing the bonding wire, either partially or wholly, with a reinforcing material after bonding work.

18. A method to produce a semiconductor device using a bonding wire for linking a semiconductor terminal to a connecting terminal for an outside circuit, characterized by including:
a process to link the semiconductor terminal with the connecting terminal using the bonding wire; and
a process to reinforce the bonding wire by coating it, either partially or wholly, with metal or inorganic material such as a ceramic.

19. A method to produce a semiconductor device using a bonding wire for linking a semiconductor terminal to a connecting terminal for an outside circuit, characterized by including:
a process to link the semiconductor terminal with the connecting terminal using the bonding wire;
a process to reinforce the bonding wire by coating it, either partially or wholly, with a metal or an inorganic material such as a ceramic; and
a process to coat or seal the area, covering the semiconductor, the bonding wires and the connecting terminals, with resin.

20. A method to produce a semiconductor device according to claim 18 or 19 characterized by coating the bonding wire, either partially or wholly, by electrolytic or electroless plating of metal in the process to reinforce the bonding wire.

21. A method to produce a semiconductor device using a bonding wire for linking a semiconductor terminal to a connecting terminal for an outside circuit, according to any one of claims 16 to 20, characterized by including a process to subject the bonding wire to a heat treatment at a temperature of 50° C. or higher after the process to reinforce the wire by the metal coating.
